(19) United States
(12) Patent Application Publication
(10) Pub. No.: US 2019/0280133 A1
(43) Pub. Date: Sep. 12, 2019

(54) SEED LAYER FOR IMPROVED CONTACT ON A SILICON WAFER

(71) Applicant: Heraeus Precious Metals North America Conshohocken LLC, West Conshohocken, PA (US)

(72) Inventor: Vinodh Chandrasekaran, Malvern, PA (US)

(21) Appl. No.: 15/916,542

(22) Filed: Mar. 9, 2018

(51) Int. Cl. H01L 31/0224; H01L 21/768; H01L 31/18; H01L 31/06; H01L 31/02

(52) U.S. Cl. CPC H01L 31/02245; H01L 21/76871; H01L 31/02008; H01L 31/06; H01L 31/1804

(57) ABSTRACT

The invention provides a seed layer paste for contacting a solar cell electrode with a low silver laydown and yet provides a higher voltage and a comparable solar efficiency. The seed layer paste includes: 1) a silver particle at 0.1-50 wt %; 2) at least one glass frit at 5-70 wt %; and 3) an organic vehicle at 20-95 wt %. The invention also provides a method of forming a solar cell by applying the seed layer paste of the invention to a surface of a silicon wafer to form a seed layer; applying on top of the seed layer a second composition containing a silver particle, at least one glass frit, and an organic vehicle; and firing the silicon wafer with the seed layer paste and the second composition.

### TECHNICAL FIELD

The invention relates to a seed layer paste for use in a solar cell electrode. The seed layer paste comprises: a silver particle, a glass frit, and an organic vehicle. The seed layer paste contains a high glass frit content and a small amount of silver content. The seed layer functions as a contact layer. On top of the seed layer paste is then printed a second layer which is the electroconductive layer. The solar cells prepared according to this method demonstrate a comparable solar efficiency relative to cells containing standard electroconductive pastes.

### BACKGROUND

Solar cells are generally made of semiconductor materials, such as silicon (Si), which convert sunlight into useful electrical energy. The production of a silicon solar cell typically starts with a p-type silicon substrate in the form of a silicon wafer on which an n-type diffusion layer of the reverse conductivity type is formed by the thermal diffusion of phosphorus (P) or the like. Phosphorus oxychloride (POCl₃) is commonly used as the gaseous phosphorus diffusion source, other liquid sources are phosphoric acid and the like. In the absence of any particular modification, the diffusion layer is formed over the entire surface of the silicon substrate. The p-n junction is formed where the concentration of the p-type dopant equals the concentration of the n-type dopant; conventional cells that have the p-n junction close to the illuminated side, have a junction depth between 0.05 and 0.5 μm.

After formation of this diffusion layer excess surface glass is removed from the rest of the surfaces by etching by an acid such as hydrofluoric acid. Next, an ARC layer (aka antireflective coating layer) of TiOₓ, SiOₓ, TiOₓ/SiOₓ, or, in particular, SiNₓ or Si₃N₄ is formed on the n-type diffusion layer to a thickness of between 0.05 and 0.1 μm by a process, such as, for example, plasma CVD (chemical vapor deposition). One or more passivation layers may be applied to the front and/or back side of the silicon wafer as an outer layer. The passivation layer(s) may be applied before the front electrode is formed, or before the antireflective layer is applied (if one is present). Preferred passivation layers are those which reduce the rate of electron/hole recombination in the vicinity of the electrode interface. Preferred passivation layers include, but are not limited to, silicon nitride, silicon dioxide and titanium dioxide.

A conventional solar cell structure with a p-type base typically has a negative grid electrode on the front-side of the cell and a positive electrode on the back-side. The grid electrode is typically applied by screen printing and drying a front-side silver paste (front electrode forming silver paste) on the ARC layer on the front-side of the cell. The front-side grid electrode is typically screen printed. These two dimensional electrode grid pattern known as a front contact makes a connection to the p-type (or n-type if used) emitter of silicon. In addition, a back-side silver paste and an aluminum paste are screen printed (or some other application method) and successively dried on the back-side of the substrate. Normally, the back-side silver paste is screen printed onto the silicon wafer's back-side first as at least two parallel busbars or as rectangles (tabs) ready for soldering interconnection strings (presoldered copper ribbons). The aluminum paste is then printed in the bare areas with a slight overlap over the back-side silver. In some cases, the silver paste is printed after the aluminum paste has been printed. Firing is then typically carried out in a belt furnace for a period of 1 to 5 minutes with the wafer reaching a peak temperature in the range of 700 to 900° C. The front grid electrode and the back electrodes can be fired sequentially or cofired.

Currently, areas of the SiNₓ passivation layer are etched or damaged over which the silver paste is printed by the glass contained in the paste. These damaged areas allow contact of silver crystallites in the silver paste with the underlying emitter and allow electric charge carriers to tunnel to the bulk silver. However, there is undesired recombination of electric charge that causes a reduced Voc of the solar cell. If etching or damage of the passivation layer can be controlled or limited, then metal-silicon contact can be optimized. Another function of the glass is to serve as an adhesion media for bonding conductive particles and adhering the fingers to the wafer surface. The minimization of the damage to the passivation layer may lead to a higher Voc which in turn may improve the solar cell efficiency.

The concept of separating contact mechanism with the emitter by using a first paste, and increasing conductivity by a second paste is well known in the industry in the so-called double or dual print approach. Overall this approach improves cell efficiency. However the general damage to the passivation layer by the contact paste is not changed or controlled. U.S. Pat. No. 8,486,826 describes such a double print approach with paste A comprising 0.5 to 8 wt % of glass frit and having fire-through capability and a metal paste B with 0 to 3 wt % of glass frit over the bottom set of finger lines created from paste A to form a top set of finger lines superimposing the bottom set of finger lines. However, the silver content in both pastes is high.

### SUMMARY

The invention provides a seed layer paste for use in a solar cell electrode with a low silver laydown and yet provides a comparable solar efficiency. The seed layer paste comprises: 1) a silver particle at 0.1-50 wt %; 2) at least one glass frit at 5-70 wt %; and 3) an organic vehicle at 20-95 wt %. According to another embodiment, the organic vehicle further comprises a thixatropic agent.

Another aspect of the invention is directed to a method of forming a solar cell by applying the seed layer paste of the invention to a surface of a silicon wafer to form a seed layer; applying on top of the seed layer a second composition comprising a silver particle, at least one glass frit, and an organic vehicle; and firing the silicon wafer with the seed layer paste and the second composition.

The invention also provides a solar cell formed according to the methods disclosed herein.

### DETAILED DESCRIPTION

The invention relates to a seed layer paste for use in a solar cell electrode. The seed layer paste comprises: a silver particle, a glass frit, and an organic vehicle. The seed layer paste contains a high glass frit content and a small amount of silver content compared to the standard electroconductive paste. The seed layer functions as a contact layer.

On top of the seed layer paste is then printed a second layer which is the electroconductive layer. The second layer is afforded by a second paste comprising a silver particle; at least one glass frit; and an organic vehicle. The electroconductive layer is the non-contact layer that provides lateral conductivity and transports charges.

### Seed Layer Paste

The seed layer paste of a relatively low solid content is first printed on a surface of the silicon wafer. This seed layer paste comprises: a silver particle, at least one glass frit, and an organic vehicle. The seed layer paste contains a high liquid content and a low solid content. The seed layer paste comprises: 1) a silver particle at 0.1-50 wt %; 2) at least one glass frit at 5-70 wt %; and 3) an organic vehicle at 20-95 wt %.

Typically, the silver particle is at about 0.1 wt % to about 50 wt %, within which any range or value is contemplated. In one embodiment, the silver particle is at least about 0.5 wt %, preferably at least about 1 wt %, more preferably at least about 3 wt %, more preferably at least about 5 wt %, most preferably at least about 10 wt %. In another embodiment, the silver particle is no more than about 35 wt %, preferably no more than about 25 wt %, more preferably no more than about 20 wt %. For example, in a preferred embodiment the silver particle is about 3 wt % to about 25 wt %, or about 5 wt % to about 20 wt %. All weight percentages are percentages of the seed layer paste.

The glass frit is at about 5 wt % to about 70 wt %, within which any range or value is contemplated. In one embodiment, the glass frit is at least about 10 wt %, preferably at least about 15 wt %, more preferably at least about 20 wt %. In another embodiment, the glass frit is no more than about 60 wt %, preferably no more than about 50 wt %, more preferably no more than about 40 wt %, most preferably no more than about 30 wt %. For example, in a preferred embodiment the glass frit is about 5 wt % to about 50 wt %, or about 10 wt % to about 30 wt %. All weight percentages are percentages of the seed layer paste.

The organic vehicle is at about 20 wt % to about 95 wt %, within which any range or value is contemplated. In one embodiment, the organic vehicle is at least about 35 wt %, preferably at least about 45 wt %, more preferably at least about 55 wt %. In another embodiment, the organic vehicle is no more than about 85 wt %, preferably no more than about 75 wt %, more preferably no more than about 65 wt %. For example, in a preferred embodiment the organic vehicle is about 35 wt % to about 75 wt %, or about 55 wt % to about 90 wt %. All weight percentages are percentages of the seed layer paste.

In one embodiment, the glass frit and the silver particle are in a weight ratio of 0.1:1 to 700:1, within which any range or value is contemplated. In a preferred embodiment, the glass frit and the silver particle are in a weight ratio of at least 0.4:1, preferably at least 1:1, most preferably at least 3:1, most preferably at least 10:1. In another embodiment, the glass frit and the silver particle are in a weight ratio no more than 500:1 by weight, preferably no more than 100:1, more preferably no more than 50:1, most preferably no more than 30:1. In another preferred embodiment, the glass frit and the silver particle are in a weight ratio of 0.5:1 to 10:1.

In another embodiment, the organic vehicle and the glass frit are in a weight ratio of 1:1 to 16:1, within which any range or value is contemplated. In a preferred embodiment, the organic vehicle and the glass frit are in a weight ratio of at least 3:1, preferably at least 5:1, more preferably at least 8:1. In another preferred embodiment, the organic vehicle and the glass frit are in a weight ratio no more than 12:1, preferably no more than 10:1.

The silver particle, glass frit, and organic vehicle for the seed layer paste are further addressed below in conjunction with the electroconductive paste.

### Electroconductive Paste

The second paste which is the electroconductive paste is printed as a separate layer on top of the seed layer to provide lateral conductivity and carrier charge transport to bus bars. The second layer is either superimposed 100% on the seed layer or contains the underlying seed layer by having greater line widths or length. The electroconductive paste composition according to the invention is generally comprised of metallic particles, at least one glass frit, and an organic vehicle. The electroconductive paste composition may further comprise an adhesion enhancer.

According to one embodiment, the electroconductive paste comprises about 50-95 wt % a silver particle, about 0.05-10 wt % glass frit, about 5-50 wt % organic vehicle, and optionally approximately 0.01-5 wt % of an adhesion enhancer, based upon 100% total weight of the electroconductive paste. Within each range, any subrange or value is contemplated for each component.

In a preferred embodiment, the electroconductive paste comprises at least about 60 wt %, more preferably at least about 75 wt %, most preferably at least about 85 wt % silver particle.

In another preferred embodiment, the electroconductive paste comprises at least about 0.1 wt %, or at least about 2 wt % of a glass frit.

In one embodiment, the silver particle and glass frit are in a weight ratio of 20:1 to 1000:1, within which any range or value is contemplated. In a preferred embodiment, the silver particle and glass frit are in a weight ratio of at least 50:1, at least 100:1, or at least 200:1. In another embodiment, the silver particle and glass frit are in a weight ratio no more than 750:1 by weight, or no more than 500:1.

As an example of a preferred embodiment, Paste B used in Example 1 comprises about 90 wt % of a silver particle, about 0.14 wt % of a glass frit (Bi—Si-alkali system), and about 9.8 wt % of an organic vehicle.

### Organic Vehicle for Seed Layer Paste and Electroconductive Paste

The organic vehicle of the invention provides the media by which the seed layer paste or the electroconductive paste is applied to the silicon surface to form a contact layer, or on top of the seed layer respectively. The organic vehicle used for the seed layer paste may be the same or different from that used for the electroconductive paste. Preferred organic vehicles are solutions, emulsions or dispersions formed of one or more solvents, preferably organic solvent(s), which ensure that the components of the paste are present in a dissolved, emulsified or dispersed form. Organic vehicles which provide optimal stability of the components of the seed layer paste and which provide the paste with suitable printability are preferred.

In one embodiment, the organic vehicle comprises an organic solvent and one or more of a binder (e.g., a polymer), a surfactant and a thixotropic agent, or any combination thereof. For example, in one embodiment, the organic vehicle comprises one or more binders in an organic solvent.

Preferred binders in the context of the invention are those which contribute to the formation of an electroconductive paste with favorable stability, printability, and viscosity properties. Binders are well known in the art. All binders which are known in the art, and which are considered to be suitable in the context of this invention, can be employed as the binder in the organic vehicle. Preferred binders according to the invention (which often fall within the category termed “resins”) are polymeric binders, monomeric binders, and binders which are a combination of polymers and monomers. Polymeric binders can also be copolymers wherein at least two different monomeric units are contained in a single molecule. Preferred polymeric binders are those which carry functional groups in the polymer main chain, those which carry functional groups off of the main chain and those which carry functional groups both within the main chain and off of the main chain. Preferred polymers carrying functional groups in the main chain are for example polyesters, substituted polyesters, polycarbonates, substituted polycarbonates, polymers which carry cyclic groups in the main chain, poly-sugars, substituted poly-sugars, polyurethanes, substituted polyurethanes, polyamides, substituted polyamides, phenolic resins, substituted phenolic resins, copolymers of the monomers of one or more of the preceding polymers, optionally with other co-monomers, or a combination of at least two thereof. According to one embodiment, the binder may be polyvinyl butyral or polyethylene. Preferred polymers which carry cyclic groups in the main chain are for example polyvinylbutylate (PVB) and its derivatives and poly-terpineol and its derivatives or mixtures thereof. Preferred poly-sugars are for example cellulose and alkyl derivatives thereof, preferably methyl cellulose, ethyl cellulose, hydroxyethyl cellulose, propyl cellulose, hydroxypropyl cellulose, butyl cellulose and their derivatives and mixtures of at least two thereof. Other preferred polymers are cellulose ester resins, e.g., cellulose acetate propionate, cellulose acetate buyrate, and any combinations thereof. Preferred polymers which carry functional groups off of the main polymer chain are those which carry amide groups, those which carry acid and/or ester groups, often called acrylic resins, or polymers which carry a combination of aforementioned functional groups, or a combination thereof. Preferred polymers which carry amide off of the main chain are for example polyvinyl pyrrolidone (PVP) and its derivatives. Preferred polymers which carry acid and/or ester groups off of the main chain are for example polyacrylic acid and its derivatives, polymethacrylate (PMA) and its derivatives or polymethylmethacrylate (PMMA) and its derivatives, or a mixture thereof. Preferred monomeric binders according to the invention are ethylene glycol based monomers, terpineol resins or rosin derivatives, or a mixture thereof. Preferred monomeric binders based on ethylene glycol are those with ether groups, ester groups or those with an ether group and an ester group, preferred ether groups being methyl, ethyl, propyl, butyl, pentyl hexyl and higher alkyl ethers, the preferred ester group being acetate and its alkyl derivatives, preferably ethylene glycol monobutylether monoacetate or a mixture thereof. Alkyl cellulose, preferably ethyl cellulose, its derivatives and mixtures thereof with other binders from the preceding lists of binders or otherwise are the most preferred binders in the context of the invention.

Preferred solvents are components which are removed from the paste to a significant extent during firing. Preferably, they are present after firing with an absolute weight reduced by at least about 80% compared to before firing, preferably reduced by at least about 95% compared to before firing. Preferred solvents are those which contribute to favorable viscosity and printability characteristics. All solvents which are known in the art, and which are considered to be suitable in the context of this invention, may be employed as the solvent in the organic vehicle. Preferred solvents are those which exist as a liquid under standard ambient temperature and pressure (SATP) (298.15 K, 25° C., 77° F.), 100 kPa (14.504 psi, 0.986 atm), preferably those with a boiling point above about 90° C. and a melting point above about −20° C. Preferred solvents are polar or non-polar, protic or aprotic, aromatic or non-aromatic. Preferred solvents include, for example, mono-alcohols, di-alcohols, poly-alcohols, mono-esters, di-esters, poly-esters, mono-ethers, di-ethers, poly-ethers, solvents which comprise at least one or more of these categories of functional group, optionally comprising other categories of functional group, preferably cyclic groups, aromatic groups, unsaturated bonds, alcohol groups with one or more O atoms replaced by heteroatoms, ether groups with one or more O atoms replaced by heteroatoms, esters groups with one or more O atoms replaced by heteroatoms, and mixtures of two or more of the aforementioned solvents. Preferred esters in this context include, for example, di-alkyl esters of adipic acid, preferred alkyl constituents being methyl, ethyl, propyl, butyl, pentyl, hexyl and higher alkyl groups or combinations of two different such alkyl groups, preferably dimethyladipate, and mixtures of two or more adipate esters. Preferred ethers in this context include, for example, diethers, preferably dialkyl ethers of ethylene glycol, preferred alkyl constituents being methyl, ethyl, propyl, butyl, pentyl, hexyl and higher alkyl groups or combinations of two different such alkyl groups, and mixtures of two diethers. Preferred alcohols in this context include, for example, primary, secondary and tertiary alcohols, preferably tertiary alcohols, terpineol and its derivatives being preferred, or a mixture of two or more alcohols. Preferred solvents which combine more than one different functional groups are tripropylene glycol methyl ether (TPM), 2,2,4-trimethyl-1,3-pentanediol monoisobutyrate, often called texanol, and its derivatives, 2-(2-ethoxyethoxy)ethanol, often known as carbitol, its alkyl derivatives, preferably methyl, ethyl, propyl, butyl, pentyl, and hexyl carbitol, preferably hexyl carbitol or butyl carbitol, and acetate derivatives thereof, preferably butyl carbitol acetate, or mixtures of at least two of the aforementioned. In a preferred embodiment, the solvent includes at least one of butyl carbitol, butyl carbitol acetate, terpineol, or mixtures thereof. These three solvents are believed to mix well with the styrene-butadiene-styrene block copolymer.

The organic solvent may be present in an amount of at least about 50 wt %, and more preferably at least about 60 wt %, and more preferably at least about 70 wt %, based upon 100% total weight of the organic vehicle. At the same time, the organic solvent may be present in an amount of no more than about 95 wt %, and more preferably no more than about 90 wt %, based upon 100% total weight of the organic vehicle.

The organic vehicle may also comprise a surfactant and/or additives. Suitable surfactants are those which contribute to the formation of a seed layer paste with favorable printability and viscosity characteristics. All surfactants which are known in the art, and which are considered to be suitable in the context of this invention, may be employed as the surfactant in the organic vehicle. Preferred surfactants are those based on linear chains, branched chains, aromatic chains, fluorinated chains, polyether chains and combinations thereof. Preferred surfactants include, but are not limited to, single chained, double chained or poly chained polymers. Preferred surfactants may have non-ionic, anionic, cationic, amphiphilic, or zwitterionic heads. Preferred surfactants may be polymeric and monomeric or a mixture thereof. Preferred surfactants may have pigment affinic groups, preferably hydroxyfunctional carboxylic acid esters with pigment affinic groups (e.g., DISPERBYK®-108, manufactured by BYK USA, Inc.), acrylate copolymers with pigment affinic groups (e.g., DISPERBYK®-116, manufactured by BYK USA, Inc.), modified polyethers with pigment affinic groups (e.g., TEGO® DISPERS 655, manufactured by Evonik Tego Chemie GmbH), and other surfactants with groups of high pigment affinity (e.g., Duomeen TDO® manufactured by Akzo Nobel N.V.). Other preferred polymers not in the above list include, but are not limited to, polyethylene oxide, polyethylene glycol and its derivatives, and alkyl carboxylic acids and their derivatives or salts, or mixtures thereof. The preferred polyethylene glycol derivative is poly(ethyleneglycol)acetic acid. Preferred alkyl carboxylic acids are those with fully saturated and those with singly or poly unsaturated alkyl chains or mixtures thereof. Preferred carboxylic acids with saturated alkyl chains are those with alkyl chains lengths in a range from about 8 to about 20 carbon atoms, preferably C₉H₁₉COOH (capric acid), C₁₁H₂₃COOH (lauric acid), C₁₃H₂₇COOH (myristic acid) C₁₅H₃₁COOH (palmitic acid), C₁₇H₃₅COOH (stearic acid), or salts or mixtures thereof. Preferred carboxylic acids with unsaturated alkyl chains are C₁₈H₃₄O₂ (oleic acid) and C₁₈H₃₂O₂ (linoleic acid).

The organic vehicle may also comprise one or more thixotropic agents and/or other additives. Any thixotropic agent known to one having ordinary skill in the art may be used with the organic vehicle of the invention. For example, without limitation, thixotropic agents may be derived from natural origin or they may be synthesized. Preferred thixotropic agents include, but are not limited to, castor oil and its derivatives, inorganic clays, polyamides and its derivatives, fumed silica, carboxylic acid derivatives, preferably fatty acid derivatives (e.g., C₉H₁₉COOH (capric acid), C₁₁H₂₃COOH (lauric acid), C₁₃H₂₇COOH (myristic acid) C₁₅H₃₁COOH (palmitic acid), C₁₇H₃₅COOH (stearic acid) C₁₈H₃₄O₂ (oleic acid), C₁₈H₃₂O₂ (linoleic acid)), or combinations thereof. Commercially available thixotropic agents, such as, for example, Thixotrol® MAX, Thixotrol® ST, or THIXCIN® E, may also be used.

Preferred additives in the organic vehicle are those materials which are distinct from the aforementioned components and which contribute to favorable properties of the electroconductive composition, such as advantageous viscosity, printability, and stability characteristics. Additives known in the art, and which are considered to be suitable in the context of the invention, may be used. Preferred additives include, but are not limited to, viscosity regulators, stabilizing agents, inorganic additives, thickeners, emulsifiers, dispersants and pH regulators.

According to one embodiment, the viscosity of the seed layer paste or the electroconductive paste is preferably at least 15 kcps and no more than about 100 kcps, preferably at least about 15 kcps, and no more than about 50 kcps.

### Silver Particles for Seed Layer Paste and Electroconductive Paste

The seed layer paste or the electroconductive paste comprises a silver particle. The silver particle used for the seed layer paste may be the same or different from that used for the electroconductive paste. The preferred silver particles include, but are not limited to, elemental metals, alloys, metal derivatives, mixtures of at least two metals, mixtures of at least two alloys or mixtures of at least one metal with at least one alloy.

The seed layer paste may comprise about 0.1 wt % to about 50 wt % of a silver particle, within which any range or value is contemplated. In one embodiment, the silver particle is at least about 0.5 wt %, preferably at least about 1 wt %, more preferably at least about 3 wt %, most preferably at least about 5 wt %. In another embodiment, the silver particle is no more than about 35 wt %, preferably no more than about 25 wt %, more preferably no more than about 20 wt %. For example, in a preferred embodiment the silver particle is about 3 wt % to about 25 wt %, or about 5 wt % to about 20 wt %. All weight percentages are percentages of the seed layer paste.

The electroconductive paste comprises about 50-95 wt % a silver particle, within which any range or value is contemplated. In a preferred embodiment, the electroconductive paste comprises at least about 60 wt %, more preferably at least about 75 wt %, most preferably at least about 85 wt % silver particle.

Suitable silver derivatives include, for example, silver alloys and/or silver salts, such as silver halides (e.g., silver chloride), silver oxide, silver nitrate, silver acetate, silver trifluoroacetate, silver orthophosphate, and combinations thereof. In another embodiment, the silver particles may comprise a metal or alloy coated with one or more different metals or alloys, for example copper particles coated with silver.

The silver particles may be present with a surface coating, either organic or inorganic. Any such coating known in the art, and which is considered to be suitable in the context of the invention, may be employed on the metallic particles. Preferred organic coatings are those coatings which promote dispersion into the organic vehicle. Preferred inorganic coatings are those coatings which regulate sintering and promote adhesive performance of the resulting seed layer paste. If such a coating is present, it is preferred that the coating correspond to no more than about 5 wt %, preferably no more than about 2 wt %, and most preferably no more than about 1 wt %, based on 100% total weight of the metallic particles.

The silver particles can exhibit a variety of shapes, sizes, and specific surface areas. Some examples of shapes include, but are not limited to, spherical, angular, elongated (rod or needle like) and flat (sheet like). The silver particles may also be present as a combination of particles with different shapes, such as, for example, a combination of spherical metallic particles and flake-shaped metallic particles.

Another characteristic of the silver particles is its average particle size, d₅₀. The d₅₀ is the median diameter or the medium value of the particle size distribution. It is the value of the particle diameter at 50% in the cumulative distribution. Particle size distribution may be measured via laser diffraction, dynamic light scattering, imaging, electrophoretic light scattering, or any other methods known in the art. Specifically, particle size according to the invention is determined in accordance with ISO 13317-3:2001. As set forth herein, a Horiba LA-910 Laser Diffraction Particle Size Analyzer connected to a computer with an LA-910 software program is used to determine the median particle diameter. The relative refractive index of the metallic particle is chosen from the LA-910 manual and entered into the software program. The test chamber is filled with deionized water to the proper fill line on the tank. The solution is then circulated by using the circulation and agitation functions in the software program. After one minute, the solution is drained. This is repeated an additional time to ensure the chamber is clean of any residual material. The chamber is then filled with deionized water for a third time and allowed to circulate and agitate for one minute. Any background particles in the solution are eliminated by using the blank function in the software. Ultrasonic agitation is then started, and the metallic particles are slowly added to the solution in the test chamber until the transmittance bars are in the proper zone in the software program. Once the transmittance is at the correct level, the laser diffraction analysis is run and the particle size distribution of the metallic component is measured and given as d₅₀.

It is preferred that the median particle diameter ids( )of the silver particles be at least about 0.1 μm, and preferably at least about 0.5 μm. At the same time, the d₅₀ is preferably no more than about 5 μm, and more preferably no more than about 4 μm.

In a preferred embodiment, the silver particles comprise a combination of at least two types of silver particles such as silver particles having different particle sizes.

Another way to characterize the shape and surface of a particle is by its specific surface area. Specific surface area is a property of solids equal to the total surface area of the material per unit mass, solid, or bulk volume, or cross sectional area. It is defined either by surface area divided by mass (with units of m²/g) or surface area divided by volume (units of m⁻¹). The specific surface area may be measured by the BET (Brunauer-Emmett-Teller) method, which is known in the art. As set forth herein, BET measurements are made in accordance with DIN ISO 9277:1995. A Monosorb Model MS-22 instrument (manufactured by Quantachrome Instruments), which operates according to the SMART method (Sorption Method with Adaptive dosing Rate), is used for the measurement. As a reference material, aluminum oxide (available from Quantachrome Instruments as surface area reference material Cat. No. 2003) is used. Samples are prepared for analysis in the built-in degas station. Flowing gas (30% N₂ and 70% He) sweeps away impurities, resulting in a clean surface upon which adsorption may occur. The sample can be heated to a user-selectable temperature with the supplied heating mantle. Digital temperature control and display are mounted on the instrument front panel. After degassing is complete, the sample cell is transferred to the analysis station. Quick connect fittings automatically seal the sample cell during transfer, and the system is then activated to commence the analysis. A dewar flask filled with coolant is manually raised, immersing the sample cell and causing adsorption. The instrument detects when adsorption is complete (2-3 minutes), automatically lowers the dewar flask, and gently heats the sample cell back to room temperature using a built-in hot-air blower. As a result, the desorbed gas signal is displayed on a digital meter and the surface area is directly presented on a front panel display. The entire measurement (adsorption and desorption) cycle typically requires less than six minutes. The technique uses a high sensitivity, thermal conductivity detector to measure the change in concentration of an adsorbate/inert carrier gas mixture as adsorption and desorption proceed. When integrated by the on-board electronics and compared to calibration, the detector provides the volume of gas adsorbed or desorbed. For the adsorptive measurement, N₂ 5.0 with a molecular cross-sectional area of 0.162 nm² at 77K is used for the calculation. A one-point analysis is performed and a built-in microprocessor ensures linearity and automatically computes the sample's BET surface area in m²/g.

According to one embodiment, the silver particles may have a specific surface area of at least about 0.1 m²/g, preferably at least about 0.2 m²/g. At the same time, the specific surface area is preferably no more than 10 m²/g, and more preferably no more than about 5 m²/g.

### Glass Frit for Seed Layer Paste and Electroconductive Paste

The glass frit for the seed layer paste limits lateral conductivity due to the silver conductivity but establishes point contacts with the underlying silicon wafer. The glass frit etches through the surface layers (e.g., diffusion layer and/or antireflective layer) of the silicon substrate, such that effective electrical contact can be made between the electroconductive paste and the silicon wafer.

The glass frit for the electroconductive paste acts as an adhesion media, facilitating the bonding between the conductive particles and the adhesion of the seed layer to the substrate.

The glass frit used for the seed layer paste may be the same or different from that used for the electroconductive paste.

According to one embodiment, the seed layer paste includes about 5 wt % to about 70 wt % of the glass frit, within which any sub-range or value is contemplated. In one embodiment, the glass frit is at least about 10 wt %, preferably at least about 15 wt %, more preferably at least about 20 wt %. In another embodiment, the glass frit is no more than about 60 wt %, preferably no more than about 50 wt %, more preferably no more than about 40 wt %, most preferably no more than about 30 wt %. For example, in a preferred embodiment the glass frit is about 5 wt % to about 50 wt %, or about 10 wt % to about 30 wt %. All weight percentages are percentages of the seed layer paste.

According to one embodiment, the elecctroconductive paste includes about 0.05 wt % to about 10 wt % of a glass frit, within which any sub-range or value is contemplated. In a preferred embodiment, the glass frit is at least about 0.1 wt %, more preferably at least about 1 wt %, based upon 100% total weight of the electroconductive paste. At the same time, the electroconductive paste preferably includes no more than about 8 wt %, and more preferably no more than about 6 wt %, based upon 100% total weight of the electroconductive paste.

Preferred glass frits are etchant materials, which may be an amorphous powder that exhibits a glass transition, crystalline or partially crystalline solids, or a mixture thereof. The glass transition temperature T_{g} is the temperature at which an amorphous substance transforms from a rigid solid to a partially mobile undercooled melt upon heating. Methods for the determination of the glass transition temperature are well known to the person skilled in the art. Specifically, the glass transition temperature T_{g} may be determined using a DSC apparatus SDT Q600 (commercially available from TA Instruments) which simultaneously records differential scanning calorimetry (DSC) and thermogravimetric analysis (TGA) curves. The instrument is equipped with a horizontal balance and furnace with a platinum/platinum-rhodium (type R) thermocouple. The sample holders used are aluminum oxide ceramic crucibles with a capacity of about 40-90 μl. For the measurements and data evaluation, the measurement software Q Advantage; Thermal Advantage Release 5.4.0 and Universal Analysis 2000, version 4.5A Build 4.5.0.5 is applied respectively. As pan for reference and sample, aluminum oxide pan having a volume of about 85 μl is used. An amount of about 10-50 mg of the sample is weighted into the sample pan with an accuracy of 0.01 mg. The empty reference pan and the sample pan are placed in the apparatus, the oven is closed and the measurement started. A heating rate of 10 K/min is employed from a starting temperature of 25° C. to an end temperature of 1000° C. The balance in the instrument is always purged with nitrogen (N₂ 5.0) and the oven is purged with synthetic air (80% N₂ and 20% O₂ from Linde) with a flow rate of 50 ml/min. The first step in the DSC signal is evaluated as glass transition using the software described above, and the determined onset value is taken as the temperature for T_{g}.

Preferably, the T_{g} is below the desired firing temperature of the electroconductive paste. According to the invention, preferred glass frits have a T_{g} of at least about 200° C., and preferably at least about 250° C. At the same time, preferred glass frits have a T_{g} of no more than about 900° C., preferably no more than about 800° C., and most preferably no more than about 700° C.

The glass frit may include elements, oxides, compounds which generate oxides upon heating, and/or mixtures thereof. According to one embodiment, the glass frit is lead-based and may include lead oxide or other lead-based compounds including, but not limited to, salts of lead halides, lead chalcogenides, lead carbonate, lead sulfate, lead phosphate, lead nitrate and organometallic lead compounds or compounds that can form lead oxides or salts during thermal decomposition, or any combinations thereof. In another embodiment, the glass frit may be lead-free. The term “lead-free” indicates that the glass frit has less than 0.5 wt % lead, based upon 100% total weight of the glass frit. The glass frit may include other oxides or compounds known to one skilled in the art, including, but not limited to, silicon, boron, aluminum, bismuth, lithium, sodium, magnesium, zinc, titanium, zirconium oxides, or compounds thereof. In one embodiment, the glass composition comprises a tungsten-lead-silicon-phosphorus-boron-oxide.

In addition to the components recited above, the glass frit may also comprise other oxides or other compounds of magnesium, nickel, tellurium, tungsten, zinc, gadolinium, antimony, cerium, zirconium, titanium, manganese, lead, tin, ruthenium, silicon, cobalt, iron, copper, bismuth, boron, and chromium, or any combination of at least two thereof, compounds which can generate those metal oxides upon firing, or a mixture of at least two of the aforementioned metals, a mixture of at least two of the aforementioned oxides, a mixture of at least two of the aforementioned compounds which can generate those metal oxides on firing, or mixtures of two or more of any of the above mentioned. Other materials which may be used to form the inorganic oxide particles include, but are not limited to, germanium oxide, vanadium oxide, molybdenum oxide, niobium oxide, indium oxide, other alkaline and alkaline earth metal (e.g., potassium, rubidium, caesium, calcium, strontium, and barium) compounds, rare earth oxides (e.g., lanthanum oxide, cerium oxides), and phosphorus oxides.

It is well known to the person skilled in the art that glass frit particles can exhibit a variety of shapes, sizes, and surface area to volume ratios. The glass particles may exhibit the same or similar shapes (including length:width:thickness ratio) as may be exhibited by the conductive metallic particles, as discussed herein. Glass frit particles with a shape, or combination of shapes, which favor improved electrical contact of the produced electrode are preferred. It is preferred that the median particle diameter ids( )of the glass frit particles (as set forth above with respect to the conductive metallic particles) be at least about 0.1 μm. At the same time, it is preferred that the d₅₀ of the glass frit be no more than about 10 μm, more preferably no more than about 5 μm, and most preferably no more than about 3.5 μm. In one embodiment, the glass frit particles have a specific surface area of at least about 0.5 m²/g, preferably at least about 1 m²/g, and most preferably at least about 2 m²/g. At the same time, it is preferred that the specific surface area be no more than about 15 m²/g, preferably no more than about 10 m²/g.

According to another embodiment, the glass frit particles may include a surface coating. Any such coating known in the art and which is considered to be suitable in the context of the invention can be employed on the glass frit particles. Preferred coatings according to the invention include those coatings which promote dispersion of the glass in the organic vehicle and improved contact of the electroconductive paste. If such a coating is present, it is preferred that the coating correspond to no more than about 10 wt %, preferably no more than about 8 wt %, most preferably no more than about 5 wt %, in each case based on the total weight of the glass frit particles.

In a preferred embodiment, a Pb-Te-alkaline-alkaline earth glass frit is used in the seed layer paste, for example a Pb—Te—Li—Bi—W—Mg glass frit or a Pb-free Te—Li—Zn—Bi—Mg glass frit. Any other glass frit may also be used. The glass frit is not limited to any single type. A combination of glass frits is also contemplated for use in the seed layer paste.

In another preferred embodiment, a Pb—Bi—Zn—W—Mg glass frit is used in the electroconductive paste. The glass frit is not limited to any single type. A combination of glass fits is also contemplated for use in the electroconductive paste.

### Additives

Preferred additives are components added to the paste, in addition to the other components explicitly mentioned, which contribute to increased electrical performance of the paste, of the electrodes produced thereof, or of the resulting solar cell. In addition to additives present in the glass frit and in the vehicle, additives can also be present in the electroconductive paste separately. Preferred additives include, but are not limited to, thixotropic agents, surfactants, viscosity regulators, emulsifiers, stabilizing agents or pH regulators, inorganic additives, thickeners, dispersants, adhesion enhancers, or a combination of at least two thereof. Preferred inorganic oxides or organometallic additives include, but are not limited to, Mg, Ni, Te, W, Zn, Mg, Gd, Ce, Zr, Ti, Mn, Sn, Ru, Co, Fe, Rh, V, Y, Sb, P, Cu and Cr or a combination of at least two thereof, preferably Zn, Sb, Mn, Ni, W, Te, Rh, V, Y, Sb, P and Ru, or a combination of at least two thereof, oxides thereof, compounds which can generate those metal oxides on firing, or a mixture of at least two of the aforementioned metals, a mixture of at least two of the aforementioned oxides, a mixture of at least two of the aforementioned compounds which can generate those metal oxides on firing, or mixtures of two or more of any of the above mentioned. In a preferred embodiment, the electroconductive paste comprises zinc oxide. In another preferred embodiment, the seed layer paste comprises ZnO, and/or Li₃PO₄.

According to one embodiment, the paste may include at least about 0.01 wt % additive(s). At the same time, the paste preferably includes no more than about 10 wt % additive(s), preferably no more than about 5 wt %, and most preferably no more than about 2 wt %, based upon 100% total weight of the paste. For example, the electroconductive paste may optionally comprise about 0.01-5 wt % of an adhesion enhancer.

### Forming the Seed Layer Paste or Electroconductive Paste

To form a seed layer paste or electroconductive paste, the glass frit materials are combined with the silver particles and organic vehicle using any method known in the art for preparing a paste composition. The method of preparation is not critical, as long as it results in a homogenously dispersed paste. The components can be mixed, such as with a mixer, then passed through a three roll mill, for example, to make a dispersed uniform paste. In addition to mixing all of the components together simultaneously, the raw glass frit materials can be co-milled with silver particles, for example, in a ball mill for 2-24 hours to achieve a homogenous mixture of glass frit and silver particles, which are then mixed with the organic vehicle.

### Kit

The invention also relates to a kit comprising a seed layer paste and a conductive layer paste. The components for each paste may be premixed, separated packaged, or have some components premixed and some other components separated packaged. The seed layer paste and the conductive layer paste are according to any of the aspects described herein.

### Solar Cells

The invention also relates to a solar cell. In one aspect, the solar cell comprises a semiconductor substrate (e.g., a silicon wafer), a seed layer, and an electroconductive layer according to any of the embodiments described herein.

In another aspect, the invention relates to a metallization structure on a solar cell prepared by a process which includes:
a. providing a silicon wafer and a first composition, wherein the first composition comprising
   i. a silver particle at 0.1-50 wt %;
   ii. at least one glass frit at 5-70 wt %; and
   iii. an organic vehicle at 20-95 wt %;
b. applying the first composition to a surface of the silicon wafer to form a seed layer;
c. providing a second composition comprising
   i. a silver particle;
   ii. at least one glass frit; and
   iii. an organic vehicle;
d. applying the second composition on top of the seed layer prepared from the first composition to form an electroconductive layer, and
e. firing the silicon wafer with the first composition and the second composition.

In step d, the second composition may be superimposed on the seed layer, or cover additional areas outside of the seed layer. Thus, the first composition and the second composition together form finger lines. In some instances, busbars may also be formed with the second composition, or with another adequate paste composition.

The invention also relates to a metallization structure on a solar cell comprising the seed layer and the electroconductive layer over the seed layer. In some instances, the electroconductive layer is superimposed on the seed layer. In other instances, the electroconductive layer covers additional areas uncovered by the seed layer. Thus, in a preferred embodiment, the fingerlines comprise the seed layer and the electroconductive layer. In another embodiment, the intersecting busbars comprise the electroconductive layer without the underlying seed layer. The paste used for electroconductive layer for the fingerlines may be the same or different from the paste used for the busbars.

### Silicon Wafer

Preferred wafers according to the invention have regions, among other regions of the solar cell, capable of absorbing light with high efficiency to yield electron-hole pairs and separating holes and electrons across a boundary with high efficiency, preferably across a p-n junction boundary. Preferred wafers according to the invention are those comprising a single body made up of a front doped layer and a back doped layer.

Preferably, the wafer comprises appropriately doped tetravalent elements, binary compounds, tertiary compounds or alloys. Preferred tetravalent elements in this context include, but are not limited to, silicon, germanium, or tin, preferably silicon. Preferred binary compounds include, but are not limited to, combinations of two or more tetravalent elements, binary compounds of a group III element with a group V element, binary compounds of a group II element with a group VI element or binary compounds of a group IV element with a group VI element. Preferred combinations of tetravalent elements include, but are not limited to, combinations of two or more elements selected from silicon, germanium, tin or carbon, preferably SiC. The preferred binary compounds of a group III element with a group V element is GaAs. According to a preferred embodiment of the invention, the wafer is silicon. The foregoing description, in which silicon is explicitly mentioned, also applies to other wafer compositions described herein.

The p-n junction boundary is located where the front doped layer and back doped layer of the wafer meet. In an n-type solar cell, the back doped layer is doped with an electron donating n-type dopant and the front doped layer is doped with an electron accepting or hole donating p-type dopant. In a p-type solar cell, the back doped layer is doped with p-type dopant and the front doped layer is doped with n-type dopant. According to a preferred embodiment of the invention, a wafer with a p-n junction boundary is prepared by first providing a doped silicon substrate and then applying a doped layer of the opposite type to one face of that substrate.

The doped silicon substrate can be prepared by any method known in the art and considered suitable for the invention. Preferred sources of silicon substrates according to the invention include, but are not limited to, mono-crystalline silicon, multi-crystalline silicon, amorphous silicon and upgraded metallurgical silicon, most preferably mono-crystalline silicon or multi-crystalline silicon. Doping to form the doped silicon substrate can be carried out simultaneously by adding the dopant during the preparation of the silicon substrate, or it can be carried out in a subsequent step. Doping subsequent to the preparation of the silicon substrate can be carried out by gas diffusion epitaxy, for example. Doped silicon substrates are also readily commercially available. According to one embodiment, the initial doping of the silicon substrate may be carried out simultaneously to its formation by adding dopant to the silicon mix. According to another embodiment, the application of the front doped layer and the highly doped back layer, if present, may be carried out by gas-phase epitaxy. This gas phase epitaxy is preferably carried out at a temperature of at least about 500° C., preferably at least about 600° C., and most preferably at least about 650° C. At the same time, the temperature is preferably no more than about 900° C., preferably no more than about 800° C., and most preferably no more than about 750° C. The gas phase epitaxy is preferably carried out at a pressure of at least about 2 kPa, preferably at least about 10 kPa, and most preferably at least about 40 kPa. At the same, the pressure is preferably no more than about 100 kPa, preferably no more than about 80 kPa, and most preferably no more than about 70 kPa.

It is known in the art that silicon substrates can exhibit a number of shapes, surface textures and sizes. The shape of the substrate may include cuboid, disc, wafer and irregular polyhedron, to name a few. According to a preferred embodiment of the invention, the wafer is a cuboid with two dimensions which are similar, preferably equal, and a third dimension which is significantly smaller than the other two dimensions. The third dimension may be at least 100 times smaller than the first two dimensions. Further, silicon substrates with rough surfaces are preferred. One way to assess the roughness of the substrate is to evaluate the surface roughness parameter for a sub-surface of the substrate, which is small in comparison to the total surface area of the substrate, preferably less than about one hundredth of the total surface area, and which is essentially planar. The value of the surface roughness parameter is given by the ratio of the area of the sub-surface to the area of a theoretical surface formed by projecting that sub-surface onto the flat plane best fitted to the sub-surface by minimizing mean square displacement. A higher value of the surface roughness parameter indicates a rougher, more irregular surface and a lower value of the surface roughness parameter indicates a smoother, more even surface. According to the invention, the surface roughness of the silicon substrate is preferably modified so as to produce an optimum balance between a number of factors including, but not limited to, light absorption and adhesion to the surface.

The two larger dimensions of the silicon substrate can be varied to suit the application required of the resultant solar cell. It is preferred according to the invention for the thickness of the silicon wafer to be below about 0.5 mm, more preferably below about 0.3 mm, and most preferably below about 0.2 mm. Some wafers have a minimum thickness of 0.01 mm or more.

It is preferred that the front doped layer be thin in comparison to the back doped layer. It is also preferred that the front doped layer have a thickness of at least about 0.1 μm, and preferably no more than about 10 μm, preferably no more than about 5μm, and most preferably no more than about 2μm.

A highly doped layer can be applied to the back face of the silicon substrate between the back doped layer and any further layers. Such a highly doped layer is of the same doping type as the back doped layer and such a layer is commonly denoted with a+ (n+-type layers are applied to n-type back doped layers and p+-type layers are applied to p-type back doped layers). This highly doped back layer serves to assist metallization and improve electroconductive properties. It is preferred according to the invention for the highly doped back layer, if present, to have a thickness of at least 1μm, and preferably no more than about 100 μm, preferably no more than about 50 μm and most preferably no more than about 15 μm.

### Dopants

Preferred dopants are those which, when added to the silicon wafer, form a p-n junction boundary by introducing electrons or holes into the band structure. It is preferred that the identity and concentration of these dopants is specifically selected so as to tune the band structure profile of the p-n junction and set the light absorption and conductivity profiles as required. Preferred p-type dopants include, but are not limited to, those which add holes to the silicon wafer band structure. All dopants known in the art and which are considered suitable in the context of the invention can be employed as p-type dopants. Preferred p-type dopants include, but are not limited to, trivalent elements, particularly those of group 13 of the periodic table. Preferred group 13 elements of the periodic table in this context include, but are not limited to, boron, aluminum, gallium, indium, thallium, or a combination of at least two thereof, wherein boron is particularly preferred.

Preferred n-type dopants are those which add electrons to the silicon wafer band structure. Preferred n-type dopants are elements of group 15 of the periodic table. Preferred group 15 elements of the periodic table in this context include, but are not limited to, nitrogen, phosphorus, arsenic, antimony, bismuth or a combination of at least two thereof, wherein phosphorus is particularly preferred.

As described above, the various doping levels of the p-n junction can be varied so as to tune the desired properties of the resulting solar cell. Doping levels are measured using secondary ion mass spectroscopy.

According to certain embodiments, the semiconductor substrate (i.e., silicon wafer) exhibits a sheet resistance above about 60 Ω/□, such as above about 65 Ω/□, 70 Ω/□, 90 Ω/□ or 100 Ω/□. For measuring the sheet resistance of a doped silicon wafer surface, the device “GP4-Test Pro” equipped with software package “GP-4 Test 1.6.6 Pro” (available from GP Solar GmbH) is used. For the measurement, the four point measuring principle is applied. The two outer probes apply a constant current and two inner probes measure the voltage. The sheet resistance is deduced using the Ohmic law in Ω/□. To determine the average sheet resistance, the measurement is performed on 25 equally distributed spots of the wafer. In an air conditioned room with a temperature of 22±1 ° C., all equipment and materials are equilibrated before the measurement. To perform the measurement, the “GP-Test.Pro” is equipped with a 4-point measuring head (Part Number 04.01.0018) with sharp tips in order to penetrate the anti-reflection and/or passivation layers. A current of 10 mA is applied. The measuring head is brought into contact with the non metalized wafer material and the measurement is started. After measuring 25 equally distributed spots on the wafer, the average sheet resistance is calculated in Ω/□.

### Solar Cell Structure

A contribution to achieving at least one of the above described objects is made by a solar cell obtainable from a process according to the invention. Preferred solar cells according to the invention are those which have a high efficiency, in terms of proportion of total energy of incident light converted into electrical energy output, and those which are light and durable. At a minimum, a solar cell includes: (i) front electrodes, (ii) a front doped layer, (iii) a p-n junction boundary, (iv) a back doped layer, and (v) soldering pads. The solar cell may also include additional layers for chemical/mechanical protection.

### Antireflective Layer

According to the invention, an antireflective layer may be applied as the outer layer before the electrode is applied to the front face of the solar cell. All antireflective layers known in the art and which are considered to be suitable in the context of the invention can be employed. Preferred antireflective layers are those which decrease the proportion of incident light reflected by the front face and increase the proportion of incident light crossing the front face to be absorbed by the wafer. Antireflective layers which give rise to a favorable absorption/reflection ratio, are susceptible to etching by the electroconductive paste, are otherwise resistant to the temperatures required for firing of the electroconductive paste, and do not contribute to increased recombination of electrons and holes in the vicinity of the electrode interface, are preferred. Preferred antireflective layers include, but are not limited to, SiNₓ, SiO₂, Al₂O₃, TiO₂ or mixtures of at least two thereof and/or combinations of at least two layers thereof. According to a preferred embodiment, the antireflective layer is SiNx, in particular where a silicon wafer is employed.

The thickness of antireflective layers is suited to the wavelength of the appropriate light. According to a preferred embodiment of the invention, the antireflective layers have a thickness of at least 20 nm, preferably at least 40 nm, and most preferably at least 60 nm. At the same time, the thickness is preferably no more than about 300 nm, more preferably no more than about 200 nm, and most preferably no more than about 90 nm.

### Passivation Layers

One or more passivation layers may be applied to the front and/or back side of the silicon wafer as an outer layer. The passivation layer(s) may be applied before the front electrode is formed, or before the antireflective layer is applied (if one is present). Preferred passivation layers are those which reduce the rate of electron/hole recombination in the vicinity of the electrode interface. Any passivation layer which is known in the art and which is considered to be suitable in the context of the invention can be employed. Preferred passivation layers according to the invention include, but are not limited to, silicon nitride, silicon dioxide and titanium dioxide. According to a more preferred embodiment, silicon nitride is used. It is preferred for the passivation layer to have a thickness of at least 0.1 nm, preferably at least 10 nm, and most preferably at least 30 nm. As the same time, the thickness is preferably no more than about 2 μm, preferably no more than about 1 μm, and most preferably no more than about 200 nm.

### Additional Protective Layers

In addition to the layers described above, further layers can be added for mechanical and chemical protection. The cell can be encapsulated to provide chemical protection. According to a preferred embodiment, transparent polymers, often referred to as transparent thermoplastic resins, are used as the encapsulation material, if such an encapsulation is present. Preferred transparent polymers in this context are silicon rubber and polyethylene vinyl acetate (PVA). A transparent glass sheet may also be added to the front of the solar cell to provide mechanical protection to the front face of the cell. A back protecting material may be added to the back face of the solar cell to provide mechanical protection. Preferred back protecting materials are those having good mechanical properties and weather resistance. The preferred back protection material according to the invention is polyethylene terephthalate with a layer of polyvinyl fluoride. It is preferred for the back protecting material to be present underneath the encapsulation layer (in the event that both a back protection layer and encapsulation are present).

A frame material can be added to the outside of the solar cell to give mechanical support. Frame materials are well known in the art and any frame material considered suitable in the context of the invention may be employed. The preferred frame material according to the invention is aluminum.

### Method of Preparing a Solar Cell

A solar cell may be prepared by applying the seed layer paste and the electroconductive paste of the invention to an antireflection coating, such as silicon nitride, silicon oxide, titanium oxide or aluminum oxide, on the front side of a semiconductor substrate, such as a silicon wafer. A backside electroconductive paste is then applied to the backside of the solar cell to form soldering pads, i.e. SOL 326. An aluminum paste is then applied to the backside of the substrate, overlapping the edges of the soldering pads formed from the backside electroconductive paste, to form the B SF, Toyo.

The seed layer paste and the electroconductive paste may be applied in any manner known in the art and considered suitable in the context of the invention. Examples include, but are not limited to, impregnation, dipping, pouring, dripping on, injection, spraying, knife coating, curtain coating, brushing, dispending or printing or a combination of at least two thereof. Preferred printing techniques are ink-jet printing, screen printing, tampon printing, offset printing, relief printing or stencil printing or a combination of at least two thereof. It is preferred according to the invention that the seed layer paste and the electroconductive paste are applied by printing, preferably by screen printing. Specifically, the screens preferably have mesh opening with a diameter of about 40 μm or less (e.g., about 35 μm or less, about 30 μm or less). At the same time, the screens preferably have a mesh opening with a diameter of at least 10 μm.

In a preferred embodiment, the seed layer paste is printed on a surface of the silicon wafer. Followed by drying at 150-300° C. for 20-120 seconds, the electroconductive paste is then printed over the dried seed layer. The coated wafer is then dried at 150-300° C. for 20-120 seconds.

The substrate is then subjected to one or more thermal treatment steps, such as, for example, conventional over drying, infrared or ultraviolet curing, and/or firing. In one embodiment the substrate may be fired according to an appropriate profile. Firing sinters the printed seed layer paste and the electroconductive paste so as to form contact layer and solid electrodes respectively. Firing is well known in the art and can be effected in any manner considered suitable in the context of the invention. It is preferred that firing be carried out above the T_{g} of the glass frit materials.

According to the invention, the maximum temperature set for firing is below about 900° C., preferably below about 860° C. Firing temperatures as low as about 800° C. have been employed for obtaining solar cells. Firing temperatures should also allow for effective sintering of the metallic particles to be achieved. The firing temperature profile is typically set so as to enable the burnout of organic materials from the paste composition. The firing step is typically carried out in air or in an oxygen-containing atmosphere in a belt furnace. It is preferred for firing to be carried out in a fast firing process with a total firing time of at least 30 seconds, and preferably at least 40 seconds. At the same time, the firing time is preferably no more than about 3 minutes, more preferably no more than about 2 minutes, and most preferably no more than about 1 minute. The time above 600° C. is most preferably in a range from about 3 to 7 seconds. The substrate may reach a peak temperature in the range of about 700 to 900° C. for a period of about 1 to 5 seconds. The firing may also be conducted at high transport rates, for example, about 100-700 cm/min, with resulting hold-up times of about 0.5 to 3 minutes. Multiple temperature zones, for example 3-12 zones, can be used to control the desired thermal profile.

Firing of the seed layer paste and the electroconductive paste on the front and back faces can be carried out simultaneously or sequentially. Simultaneous firing is appropriate if the pastes applied to both faces have similar, preferably identical, optimum firing conditions. Where appropriate, it is preferred for firing to be carried out simultaneously. Where firing is carried out sequentially, it is preferable for the back pastes to be applied and fired first, followed by application and firing of the pastes to the front face of the substrate.

### Measuring Properties of Solar Cell

The electrical performance of a solar cell is measured using a commercial IV-tester “cetisPV-CTL1” from Halm Elektronik GmbH. All parts of the measurement equipment as well as the solar cell to be tested are maintained at 25° C. during electrical measurement. This temperature should be measured simultaneously on the cell surface during the actual measurement by a temperature probe. The Xe Arc lamp simulates the sunlight with a known AM1.5 intensity of 1000 W/m² on the cell surface. To bring the simulator to this intensity, the lamp is flashed several times within a short period of time until it reaches a stable level monitored by the “PVCTControl 4.313.0” software of the IV-tester. The Halm IV tester uses a multi-point contact method to measure current (I) and voltage (V) to determine the solar cell's IV-curve. To do so, the solar cell is placed between the multi-point contact probes in such a way that the probe fingers are in contact with the bus bars (i.e., printed lines) of the solar cell. The numbers of contact probe lines are adjusted to the number of bus bars on the cell surface. All electrical values were determined directly from this curve automatically by the implemented software package. As a reference standard, a calibrated solar cell from ISE Freiburg consisting of the same area dimensions, same wafer material, and processed using the same front side layout, was tested and the data was compared to the certificated values. At least five wafers processed in the very same way were measured and the data was interpreted by calculating the average of each value. The software PVCTControl 4.313.0 provided values for efficiency,

The invention will now be described in conjunction with the following, non-limiting examples.

### EXAMPLE 1

Solar cells with a seed layer and an electroconductive layer were prepared using 1) Pastes 1-5 as the paste for the seed layer and 2) Paste B for the electroconductive layer. Paste B represents a standard electroconductive paste, comprising about 90 wt % silver, about 0.14 wt % glass frit (Bi—Si-alkali system), and about 9.8 wt % organic vehicle. A solar cell using Paste 0 as the single conductive layer was also prepared as a comparative. The composition in wt % of the paste is shown in Table 1 below.

TABLE 1

| | Paste 0 | Paste 1 | Paste 2 | Paste 3 | Paste 4 | Paste 5 |
|---|---|---|---|---|---|---|
| Ag 1 | | 10 | 10 | 10 | 15 | 20 |
| Ag 2 | 89 | | | | | |
| Glass Frit 1^{a} | 2.0 | 10 | 20 | 30 | 15 | 9 |
| Glass Frit 2 ^{b} | 0.25 | | | | | 1 |
| Vehicle ^{c} | 9.5 | 80 | 70 | 60 | 70 | 80 |

^{a}Comprises a Pb—Te—Li—Bi—W—Mg glass frit.
^{b} Comprises a Pb—Bi—Zn—W—Mg glass frit.
^{c} Comprises 2 wt % surfactant, 6 wt % thixotrope, 10 wt % PVB (polyvinyl butyral, BH30 from Kuraray) and 82 wt % solvent butycarbitol/butycarbitaol acetate (DOW Chemicals).

Pastes 0-5 were prepared by mixing a silver particle, a glass frit, and an organic vehicle as described in Table 1. The mixture was then milled using a three-roll mill with a first gap of about 120 microns and a second gap of about 60 microns and was passed through several times with progressively decreasing gaps (down to 20 microns for first gap and 10 microns for second gap) until it reached a homogenous consistency.

To form a seed layer, each paste was then screen printed onto a silicon wafer using a screen (380/14 mesh/10 μm EOM/100 lines). The silicon wafer was Mono Cz 156mm×156mm (full BSF; resistivity: 72 from Lerri Solar Technology Co, Ltd, Xian, China). The printing screen had an opening 15 p.m, no bus-bars, and a tension applied 24N.

Paste B was screen printed onto the seed layer to form the second layer using a screen (380/14 mesh/15 μm EOM/100 lines). The printing screen had an opening 15 μm, a bus-bar number 4, and a tension applied 24N.

The printed wafers were then dried at about 150° C. and fired in a linear 6-zone infrared furnace at 350° C., 400° C., 400° C., 480° C., 815° C., and 890° C. at 6500 mm/min speed.

The efficiency of each solar cell was measured. The results are shown in Table 2. The separation of contact layer (seed layer) and conductive layer (second layer) improves the contact mechanism as seen in the increase in Voc by 3 mV (Pastes 1-3). Parallel silver lay down per cell is reduced by more than 25%, while efficiency is similar. The glass laydown/cell is much lower (0.3 mg seed layer and 0.09 mg for second layer compared to 2 mg single print comparative Paste 0).

TABLE 2

| | | Paste 1 | Paste 2 | Paste 3 | Paste 4 | Paste 5 |
|---|---|---|---|---|---|---|
| | Paste 0 | and Paste B | and Paste B | and Paste B | and Paste B | and Paste B |
| Eta (%) | 19.55 | 17.97 | 19.18 | 19.37 | 18.42 | 18.63 |
| Voc (mv) | 0.643 | 0.646 | 0.646 | 0.646 | 0.642 | 0.643 |
| Silver Laydown | 106 | 80 ^{a} | 80 ^{a} | 80 ^{a} | 80 ^{a} | 80 ^{a} |
| (mg/cell) | | | | | | |

^{a} 79 mg Ag from Paste B and 1 mg Ag from the seed layer paste.

These and other advantages of the invention will be apparent to those skilled in the art from the foregoing specification. Accordingly, it will be recognized by those skilled in the art that changes or modifications may be made to the above described embodiments without departing from the broad inventive concepts of the invention. Specific dimensions of any particular embodiment are described for illustration purposes only. It should therefore be understood that this invention is not limited to the particular embodiments described herein, but is intended to include all changes and modifications that are within the scope and spirit of the invention.

1. A seed layer paste for a solar cell electrode comprising:
a silver particle at 0.1-50 wt %;
at least one glass frit at 5-70 wt %; and
an organic vehicle at 20-95 wt %.

2. The seed layer paste of claim 1, wherein the at least one glass frit and silver particle are in a ratio of 0.1:1 to 700:1 by weight, preferably 0.5:1 to 10:1 by weight.

3. A method of preparing a metallization structure on a solar cell comprising the steps of:
a. providing a silicon wafer and a first composition, wherein the first composition comprising based on a weight of the first composition:
i. a silver particle at 0.1-50 wt %;
ii. at least one glass frit at 5-70 wt %; and
iii. an organic vehicle at 20-95 wt %;
b. applying the first composition to a surface of the silicon wafer to form a seed layer;
c. providing a second composition comprising based on a weight of the second composition:
i. a silver particle at 50-95 wt %;
ii. at least one glass frit at 0.05-10 wt %; and
iii. an organic vehicle at 5-50 wt %;
d. applying the second composition on top of the seed layer prepared from the first composition, and
e. firing the silicon wafer with the first composition and the second composition.

4. A metallization structure on a solar cell formed according to claim 3.

5. A metallization structure on a solar cell comprising:
a seed layer comprising a first composition, comprising prior to firing a silver particle and at least one glass frit, wherein the at least one glass frit and a silver particle are in a weight ratio of 0.5:1 to 10:1; and
a conductive layer comprising a second composition, comprising prior to firing a silver particle and at least one glass frit,
wherein the conductive layer covers at least the seed layer.

6. A kit comprising:
a. a first composition comprising based on a weight of the first composition
i. a first silver particle at 0.1-50 wt %;
ii. a first glass frit at 5-70 wt %; and
iii. a first organic vehicle at 20-95 wt %,
wherein the first glass frit and the first silver particle are in a weight ratio of 1:1 to 4:1, and the first organic vehicle and the glass frit are in a weight ratio of 1:1 to 15:1, wherein the first silver particle, the first glass frit and the first organic vehicle are separate or combined; and
b. a second composition comprising based on a weight of the second composition
i. a second silver particle at 50-95 wt %;
ii. a second glass frit at 0.05-10 wt %; and
iii. a second organic vehicle at 5-50 wt %,
wherein the second silver particle, the second glass frit and the second organic vehicle are separate or combined.
